(19) United States
(12) Patent Application Publication
(10) Pub. No.: US 2023/0232654 A1
(43) Pub. Date: Jul. 20, 2023

(54) Full-color silicon-based organic light-emitting diode (OLED) structure and preparation method thereof

(71) Applicant: ANHUI SEMICONDUCTOR INTEGRATED DISPLAY TECHNOLOGY CO., LTD., Wuhu (CN)

(72) Inventors: Lei LV, Wuhu (CN); Weiwei LI, Wuhu (CN); Shengfang LIU, Wuhu (CN); Xueyuan LI, Wuhu (CN); Zhengtao ZHAO, Wuhu (CN); Song XU, Wuhu (CN)

(73) Assignee: ANHUI SEMICONDUCTOR INTEGRATED DISPLAY TECHNOLOGY CO. LTD, Wuhu (CN)

(21) Appl. No.: 18/013,927

(22) PCT Filed: Dec. 8, 2021
(86) PCT No.: PCT/CN2021/136458

§ 371 Date: Dec. 30, 2022

(30) Foreign Application Priority Data
Oct. 20, 2020 (CN) 202011122343.7

(51) Int. Cl. H10K 50/852; H10K 71/16

(52) U.S. Cl. CPC H10K 50/852; H10K 71/164; H10K 71/166; H10K 2102/351

(57) ABSTRACT

A full-color silicon-based organic light-emitting diode structure includes a metal anode layer, an organic functional layer, a metal cathode layer, an encapsulation layer, and a color filter layer. The organic functional layer includes a light-emitting layer configured to emit white light. The light-emitting layer includes a red light-emitting unit, a blue light-emitting unit, a green light-emitting unit, and a light-emitting common transport layer. The red light-emitting unit and the blue light-emitting unit are vapor-deposited on the same fine metal mask, and other structural film layers are vapor-deposited on a common metal mask. The present disclosure overcomes problems that red, green, and blue spectra cannot appear at the same time due to different lengths of red, green, and blue resonant cavities, the color gamut of the product is low due to large intensity differences, and the product life is affected due to large light loss caused by the color filter.

### CROSS REFERENCE TO THE RELATED APPLICATIONS

This application is the national phase entry of International Application No. PCT/CN2021/136458, filed on Dec. 8, 2021, which is based upon and claims priority to Chinese Patent Application No. 202011122343.7, filed on Oct. 20, 2020, the entire contents of which are incorporated herein by reference.

### TECHNICAL FIELD

The present disclosure relates to the technical field of organic light-emitting diodes (OLEDs), and in particular to a full-color silicon-based OLED structure and a preparation method thereof.

### BACKGROUND

Compared with traditional active matrix/organic light-emitting diode (AMOLED) displays, silicon-based OLED microdisplay is based on a single-crystal silicon chip and has a smaller pixel size and a higher integration level with the mature complementary metal-oxide-semiconductor transistor (CMOS) process. The silicon-based OLED microdisplay can be used to prepare near-eye displays that are comparable to large-screen displays, and thus, the silicon-based OLED microdisplay has received widespread attention. Due to its technical advantages and broad market prospect, the silicon-based OLED microdisplay may set off a new wave of near-eye displays in the military and consumer electronics fields, bringing users an unprecedented visual experience.

Limited by the preparation technology of the metal mask, the existing high pixels per inch (ppi) full-color silicon-based OLED products usually use the white OLED (WOLED) plus color filter (CF) technology. In order to achieve color display, the spectrum of WOLED usually includes a red (R) light peak, a green (G) light peak, and a blue (B) light peak. Since the R light, the G light, and the B light correspond to optical microcavities with different thicknesses, the current structure of top-emission WOLED with a single optical thickness is prone to color shift.

Therefore, in order to overcome the above technical problems, it is necessary to provide a full-color silicon-based OLED structure with low process difficulty, high product brightness, and long service life as well as a preparation method thereof.

### SUMMARY

An objective of the present disclosure is to provide a full-color silicon-based organic light-emitting diode (OLED) structure with low process difficulty, high product brightness, long service life, and a preparation method thereof. The present disclosure overcomes the problems in the prior art that red (R), green (G) and blue (B) spectra cannot appear at the same time due to different lengths of R, G, and B resonant cavities, the color gamut of the product is low due to large intensity differences, and the product life is affected due to large light loss caused by the color filter.

In order to achieve the above objective, the present disclosure provides a full-color silicon-based OLED structure, including a metal anode layer, an organic functional layer, a metal cathode layer, a polarizer layer, an encapsulation layer, and a color filter layer that are sequentially stacked from bottom to top.

The organic functional layer includes a light-emitting layer configured to emit white light toward the metal cathode layer.

The light-emitting layer includes: a red (R) light-emitting unit, a blue (B) light-emitting unit, a green (G) light-emitting unit, and a light-emitting common transport layer.

The R light-emitting unit and the B light-emitting unit are vapor-deposited on the same fine metal mask (FMM), such that the R light-emitting unit and the B light-emitting unit share a microcavity. Other structural film layers of the OLED structure are vapor-deposited on a common metal mask (CMM). In the light-emitting layer, d_{FB}−d_{G}=d_{EML-R}+d_{EML-B}, where

d_{FB} denotes a thickness of an organic layer, which corresponds to the R light-emitting unit and the B light-emitting unit, of the OLED structure;

d_{G} denotes a thickness of an organic layer, which corresponds to the G light-emitting unit, of the OLED structure;

d_{EML-R} denotes a thickness of the R light-emitting unit; and

d_{EML-B} denotes a thickness of the B light-emitting unit.

Preferably, the sum of the thickness of the R light-emitting unit and the thickness of the B light-emitting unit is:

d_{EML-R}+d_{EML-B}=70 N, where

N is a positive integer, and the thickness is in nanometers (nm).

Preferably, the thickness d_{EML-R} of the R light-emitting unit is 35-45 nm, and

the thickness d_{EML-B} of the B light-emitting unit is 25-35 nm.

Preferably, the color filter layer includes an R filter and a B filter, which are coated on light-emitting regions of the encapsulation layer. The light-emitting regions correspond to the R light-emitting unit and the B light-emitting unit, respectively.

Preferably, the organic functional layer further includes a hole injection layer, a hole transport layer, an electron transport layer, and an electron injection layer that are sequentially arranged from bottom to top.

The present disclosure further provides a preparation method for the full-color silicon-based OLED structure, including:

calculating the thicknesses of the organic layers, which respectively correspond to the R light-emitting unit, the B light-emitting unit, and the G light-emitting unit, of the OLED structure by Eq. (1);

calculating the sum of the thickness of the R light-emitting unit and the thickness of the B light-emitting unit by Eq. (2), where Eq. (1) is:

$$\sum {nd}_{i} + \frac{ϕ}{4 π} {λ}_{i} = {m}_{i} \times \frac{{λ}_{i}}{2} ;$$

where n denotes a refractive index of the organic functional layer in the OLED structure; dᵢ denotes the thickness of the organic functional layer; λᵢ denotes a resonance-enhanced wavelength of the microcavity in the OLED structure; ϕ denotes a phase shift of light reflected on surfaces of the metal anode layer and the metal cathode layer in the OLED structure; mᵢ denotes an order of an emission mode, also known as a microcavity order, which is a positive integer; and i denotes a type of a light-emitting unit;

Eq. (2) is:

d_{FB}−d_{G}=d_{EML-R}+d_{EML-B};

where d_{FB} denotes the thickness of an organic layer, which corresponds to the R light-emitting unit and the B light-emitting unit, of the OLED structure;

d_{G} denotes the thickness of an organic layer, which corresponds to the G light-emitting unit, of the OLED structure;

d_{EML-R} denotes the thickness of the R light-emitting unit; and

d_{EML-B} denotes the thickness of the B light-emitting unit;

selecting each of the structural film layers with the corresponding thickness in the OLED structure according to the calculation results from Eq. (1) and Eq. (2); and

vapor-depositing each of the structural film layers.

Preferably, the vapor-depositing each of the structural film layers includes:
S101: vapor-depositing the hole injection layer and the hole transport layer on the CMM;
S102: vapor-depositing the B light-emitting unit on the FMM;
S103: vapor-depositing the light-emitting common transport layer on the CMM;
S104: vapor-depositing the G light-emitting unit on the CMM;
S105: vapor-depositing the R light-emitting unit on the FMM;
S106: vapor-depositing the electron transport layer and the electron injection layer on the CMM; and
S107: vapor-depositing the metal cathode layer and the encapsulation layer on the CMM.

Preferably, in Eq. (1):

n is 1.75; and

λ_{R} is 618 nm, λ_{G} is 530 nm, and λ_{B} is 460 nm.

Preferably, the microcavity order m_{R} corresponding to the R light-emitting unit is 3 N;

the microcavity order m_{B} corresponding to the B light-emitting unit is 4 N; and

the microcavity order m_{G} corresponding to the G light-emitting unit is 3 N, where

the N is a positive integer.

Preferably, following the vapor-depositing of the metal cathode layer and the encapsulation layer on the CMM in S107, the method further includes:

S108: coating, by a photolithography process, the color filter layer on the light-emitting regions, which respectively correspond to the R light-emitting unit and the B light-emitting unit, of the encapsulation layer, where

the color filter layer includes the R filter and the B filter.

According to the above technical solutions, the full-color silicon-based OLED structure and the preparation method thereof provided by the present disclosure have the following beneficial effects. The R and B pixels share one FMM, and the opening size of the FMM is increased, which reduces the difficulty of FMM fabrication. Through the multi-order microcavity calculation, the thickness of the OLED structure is set to enhance the resonance of the R and B pixels. The G light-emitting unit is taken as a common layer, and the optical path difference is compensated by adjusting the thickness of the R light-emitting unit and the thickness of the B light-emitting unit, thereby reducing the processing difficulty. Since the G light-emitting unit is taken as the common layer and the R light-emitting unit and the B light-emitting unit share the FMM, only the G light is emitted in the G pixel region. Therefore, in the subsequent coating of the color filters, the green color filter is omitted, and only the R and B filters are used, which simplifies the manufacturing process of the color filters. The G spectrum is a microcavity-enhanced spectrum, so the wavelength range required for the transmittance of the R and B filters is reduced. There is no color filter in the G pixel region, which improves the luminous brightness of the G pixel region. G light emission is a major contributor to product brightness and life, so the design improves product brightness and life.

Other features and advantages of the present disclosure will be described in detail in the detailed description section, and those not mentioned herein are prior art or may be implemented by the prior art.

### BRIEF DESCRIPTION OF THE DRAWINGS

The drawings are provided for further understanding of the present disclosure and constitute part of the specification. The drawings and the detailed description of the present disclosure are intended to explain the present disclosure, rather than to limit the present disclosure. In the drawings:

FIG. 1 is a structural diagram of a full-color silicon-based organic light-emitting diode (OLED) structure according to a preferred implementation of the present disclosure;

FIG. 2 is a structural diagram of a fine metal mask (FMM) according to a preferred implementation of the present disclosure;

FIG. 3 is a flowchart of a preparation method of the full-color silicon-based OLED structure according to a preferred implementation of the present disclosure;

FIG. 4 is a flowchart of vapor-depositing each of the structural film layers of the full-color silicon-based OLED structure according to a preferred implementation of the present disclosure;

FIG. 5 shows a resonance-enhanced spectrum of a green (G) light-emitting unit when an organic layer of the full-color silicon-based OLED structure has a thickness of 454 nm according to a preferred implementation of the present disclosure; and

FIG. 6 shows a resonance-enhanced spectrum of a red (R) light-emitting unit and a blue (B) light-emitting unit when an organic layer of the full-color silicon-based OLED structure has a thickness of 524 nm according to a preferred implementation of the present disclosure.

### REFERENCE NUMERALS

1. metal anode layer; 2. hole injection layer;
3. hole transport layer: 4. light-emitting layer;
5. electron transport layer; 6. electron injection layer;
7. metal cathode layer; 8. polarizer layer;
9. encapsulation layer; 10. color filter layer;
401. B light-emitting unit; 402. light-emitting common transport layer;
403. G light-emitting unit; and 404. R light-emitting unit.

### DETAILED DESCRIPTION OF THE EMBODIMENTS

The specific implementations of the present disclosure are described in detail below with reference to the drawings. It should be understood that the specific implementations described herein are merely intended to illustrate and interpret the present disclosure, rather than to limit the present disclosure.

In the present disclosure, unless otherwise stated, the orientation terms such as “upper”, “lower”, “inner”, and “outer” only denote the orientation under normal usage or are understood by those skilled in the art and should not be viewed as a limitation of the term.

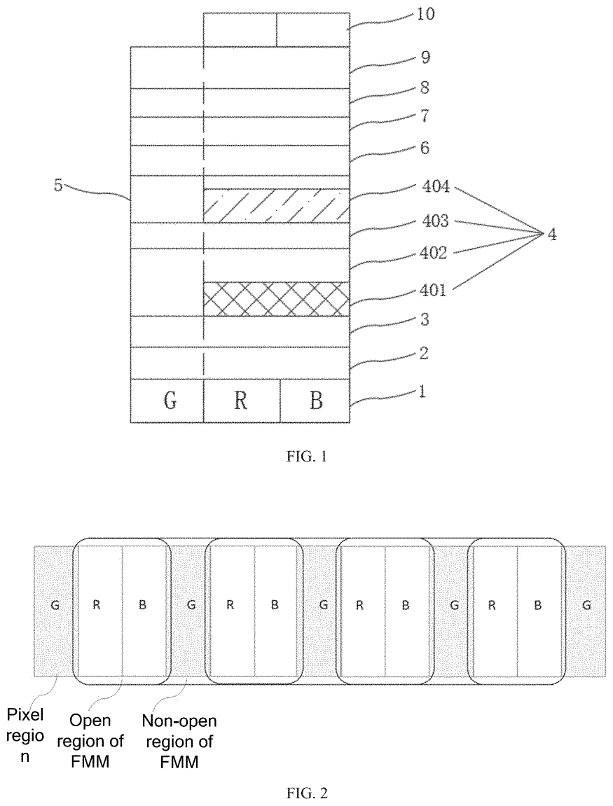

As shown in FIG. 1, the present disclosure provides a full-color silicon-based organic light-emitting diode (OLED) structure, including metal anode layer 1, an organic functional layer, metal cathode layer 7, encapsulation layer 9, and color filter layer 10 that are sequentially stacked from bottom to top.

The organic functional layer includes light-emitting layer 4 configured to emit white light toward the metal cathode layer.

The light-emitting layer includes red (R) light-emitting unit 404, blue (B) light-emitting unit 401, green (G) light-emitting unit 403, and light-emitting common transport layer 402.

The R light-emitting unit 404 and the B light-emitting unit 401 are vapor-deposited on the same fine metal mask (FMM), such that the R light-emitting unit and the B light-emitting unit share a microcavity. Other structural film layers of the OLED structure are vapor-deposited on a common metal mask (CMM). In the light-emitting layer, d_{FB}−d_{G}=d_{EML-R}+d_{EML-B}, where

d_{FB} denotes the thickness of an organic layer, which corresponds to the R light-emitting unit 404 and the B light-emitting unit 401, of the OLED structure;

d_{G} denotes the thickness of an organic layer, which corresponds to the G light-emitting unit, of the OLED structure;

d_{EML-R} denotes the thickness of the R light-emitting unit; and

d_{EML-B} denotes the thickness of the B light-emitting unit.

In the above solution, one FMM is used, that is, the R and B pixels share the FMM, and the FMM is provided with an open region shared by the R and B pixels, as shown in FIG. 2. The G light-emitting unit is taken as a common layer, and the thickness of the resonant cavity is adjusted by the thickness of the R light-emitting unit and the B light-emitting unit to compensate the resonant cavity. Thus, R light emission and B light emission are realized in the microcavity, which corresponds to the R and B pixels, of the OLED structure. That is, the B light-emitting unit and the R light-emitting unit share the microcavity, and only the G light is emitted in the G pixel region, such that only the R filter and the B filter are coated on the encapsulation layer to achieve full-color display.

The thickness of the R light-emitting unit and the thickness of the B light-emitting unit satisfy d_{FB}−d_{G}=d_{EML-R}+d_{EML-B} to achieve the effect of thickness compensation.

In a preferred implementation, the sum of the thickness of the R light-emitting unit and the thickness of the B light-emitting unit is.

d_{EML-R}+d_{EML-B}=70N, where

N is a positive integer, and the thickness is in nanometers (nm).

In a preferred implementation, the thickness d_{EML-R} of the R light-emitting unit is 35-45 nm, and the thickness d_{EML-B} of the B light-emitting unit is 25-35 nm.

In a preferred implementation, the color filter layer includes an R filter and a B filter, which are coated on light-emitting regions, which respectively correspond to the R light-emitting unit and the B light-emitting unit, of the encapsulation layer.

In a preferred implementation, the organic functional layer further includes a hole injection layer, a hole transport layer, an electron transport layer, and an electron injection layer that are sequentially arranged from bottom to top.

According to the above technical solutions, the full-color silicon-based OLED structure provided by the present disclosure has the following working principle. The R and B pixels share one FMM, and the opening size of the FMM is increased, which reduces the difficulty of FMM fabrication. Through the multi-order microcavity calculation, the thickness of the OLED structure is set to enhance the resonance of the R and B pixels. The G light-emitting unit is taken as a common layer, and the optical path difference is compensated by adjusting the thickness of the R light-emitting unit and the thickness of the B light-emitting unit, thereby reducing the processing difficulty. Since the G light-emitting unit is taken as the common layer and the R light-emitting unit and the B light-emitting unit share the FMM, only the G light is emitted in the G pixel region. Therefore, in the subsequent coating of the color filters, the green color filter is omitted, and only the R and B filters are used, which simplifies the manufacturing process of the color filters. The G spectrum is a microcavity-enhanced spectrum, so the wavelength range required for the transmittance of the R and B filters is reduced. There is no color filter in the G pixel region, which improves the luminous brightness of the G pixel region. G light emission is a major contributor to product brightness and life, so the design improves product brightness and life.

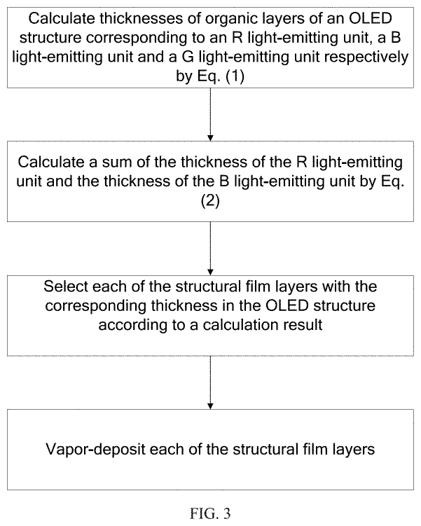

As shown in FIG. 3, the present disclosure further provides a preparation method for the full-color silicon-based OLED structure, including: The thicknesses of the organic layers, which correspond to the R light-emitting unit, the B light-emitting unit, and the G light-emitting unit, of the OLED structure are calculated respectively by Eq. (1).

The sum of the thickness of the R light-emitting unit and the thickness of the B light-emitting unit is calculated by Eq. (2), where Eq. (1) is:

$$\sum {nd}_{i} + \frac{ϕ}{4 π} {λ}_{i} = {m}_{i} \times \frac{{λ}_{i}}{2} ;$$

where n denotes a refractive index of the organic functional layer in the OLED structure; dᵢ denotes a thickness of the organic functional layer; λᵢ denotes a resonance-enhanced wavelength of the microcavity in the OLED structure; ϕ denotes a phase shift of light reflected on surfaces of the metal anode layer and the metal cathode layer in the OLED structure; mᵢ denotes an order of an emission mode, also known as a microcavity order, which is a positive integer; and i denotes a type of a light-emitting unit.

Eq. (2) is:

d^{FB}−d_{G}=d_{EML-R}+d_{EML-B};

where d_{FB} denotes the thickness of an organic layer, which corresponds to the R light-emitting unit and the B light-emitting unit, of the OLED structure;

d_{G} denotes the thickness of an organic layer, which corresponds to the G light-emitting unit, of the OLED structure;

d_{EML-R} denotes the thickness of the R light-emitting unit; and

d_{EML-B} denotes the thickness of the B light-emitting unit.

Each of the structural film layers with the corresponding thickness in the OLED structure is selected according to the calculation results of Eq. (1) and Eq. (2).

Each of the structural film layers is vapor-deposited.

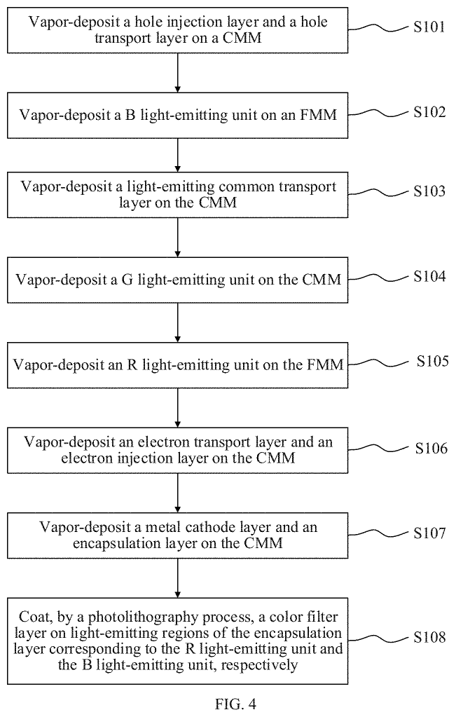

As shown in FIG. 4, in a preferred implementation of the present disclosure, the vapor-depositing of each of the structural film layers of the full-color silicon-based OLED structure includes:

S101: The hole injection layer and the hole transport layer are vapor-deposited on the CMM.

S102: The B light-emitting unit is vapor-deposited on the FMM

S103: The light-emitting common transport layer is vapor-deposited on the CMM.

S104: The G light-emitting unit is vapor-deposited on the CMM

S105: The R light-emitting unit is vapor-deposited on the FMM.

S106: The electron transport layer and the electron injection layer are vapor-deposited on the CMM.

S107: The metal cathode layer and the encapsulation layer are vapor-deposited on the CMM.

In a preferred implementation of the present disclosure, in Eq. (1):

n is 1.75: and

λ_{R} is 618 nm, λ_{G} is 530 nm, and λ_{B} is 460 nm.

In a preferred implementation of the present disclosure, the microcavity order m_{R} corresponding to the R light-emitting unit is 3 N;

the microcavity order m_{B} corresponding to the B light-emitting unit is 4 N; and

the microcavity order m_{G} corresponding to the G light-emitting unit is 3 N, where

the N is a positive integer.

In a preferred implementation of the present disclosure, following the vapor-depositing of the metal cathode layer and the encapsulation layer on the CMM in S107, the method further includes:

S108: The color filter layer is coated by a photolithography process on the light-emitting regions, which respectively correspond to the R light-emitting unit and the B light-emitting unit, of the encapsulation layer, where

the color filter layer includes the R filter and the B filter.

The preparation method of the full-color silicon-based OLED structure has the following working principle. The thicknesses of the organic layers, which respectively correspond to the R light-emitting unit, the B light-emitting unit, and the G light-emitting unit, of the OLED structure are calculated by Eq. (1). Eq. (1) is:

$$\sum {nd}_{i} + \frac{ϕ}{4 π} {λ}_{i} = {m}_{i} \times \frac{{λ}_{i}}{2} .$$

where n denotes a refractive index of the organic functional layer in the OLED structure; dᵢ denotes the thickness of the organic functional layer; λᵢ denotes a resonance-enhanced wavelength of the microcavity in the OLED structure; ϕ denotes a phase shift of light reflected on surfaces of the metal anode layer and the metal cathode layer in the OLED structure; mᵢ denotes an order of an emission mode, also known as a microcavity order, which is a positive integer; and i denotes a type of a light-emitting unit;

In this implementation, in order to simplify calculations and perform theoretical simulations, in this structure, let a refractive index of the organic layer be n=1.75, a wavelength of R be λ_{R}=618 nm, a wavelength of G be λ_{G}=530 nm, and a wavelength of B be λ_{B}=460 nm. The phase shift of light at the metal cathode layer and the metal anode layer is ignored, and let m=1,2,3, . . . , N. The thicknesses of the organic layers, which correspond to the R, G, and B light-emitting layers, of the OLED structure are shown in Table 1.

TABLE 1

| | m = 1 | m = 2 | m = 3 | m = 4 | m = 5 | m = 6 | m = 7 | m = 8 | m = 9 | . . . | m = N |
|---|---|---|---|---|---|---|---|---|---|---|---|
| R | 176.6 | 363.2 | 529.8 | 706.4 | 883 | 1059.6 | 1236.2 | 1412.8 | 1589.4 | . . . | 176.6N |
| G | 151.4 | 302.8 | 454.2 | 605.6 | 757 | 908.4 | 1059.8 | 1211.2 | 1362.6 | . . . | 151.4N |
| B | 131.4 | 262.8 | 394.2 | 525.6 | 657 | 788.4 | 919.8 | 1051.2 | 1182.6 | . . . | 131.4N |

According to the above table, the total thickness of the film layers of the OLED structure required for R, G, and B enhancement is obtained. The B and R light-emitting units share the microcavity, that is, the organic layers, which correspond to the R light-emitting unit and the B light-emitting unit, of the OLED have the same thickness. The microcavity order of the R light-emitting unit and the B light-emitting unit is determined, which is a positive integer. Therefore, the microcavity order m_{R} corresponding to the R light-emitting unit is 3 N, the microcavity order m_{B} corresponding to the B light-emitting unit is 4 N, and the microcavity order m_{G} corresponding to the G light-emitting unit is 3 N. Due to the need to control the thickness of each film layer of the OLED structure, N generally is 1. Of course, N can also take other positive integers, and the thickness changes exponentially. Therefore, m_{R}=3, m_{B}=4, and m_{G}=3. In this way, the thickness of the organic functional layer of the OLED structure is 524 nm, and the thickness of the organic layer, which corresponds to the G light-emitting unit, of the OLED structure, that is, the thickness of the common layer, is 454 nm. According to Eq. (2) d_{FB}−d_{G}=d_{EML-R}+d_{EML-B}, d_{EML-R}+d_{EML-B}=70. The R light-emitting unit and the B light-emitting unit are vapor-deposited on the same FMM. The thickness d_{EML-R} of the R light-emitting unit is 35-45 nm, and the thickness d_{EML-B} of the B light-emitting unit is 25-35 nm.

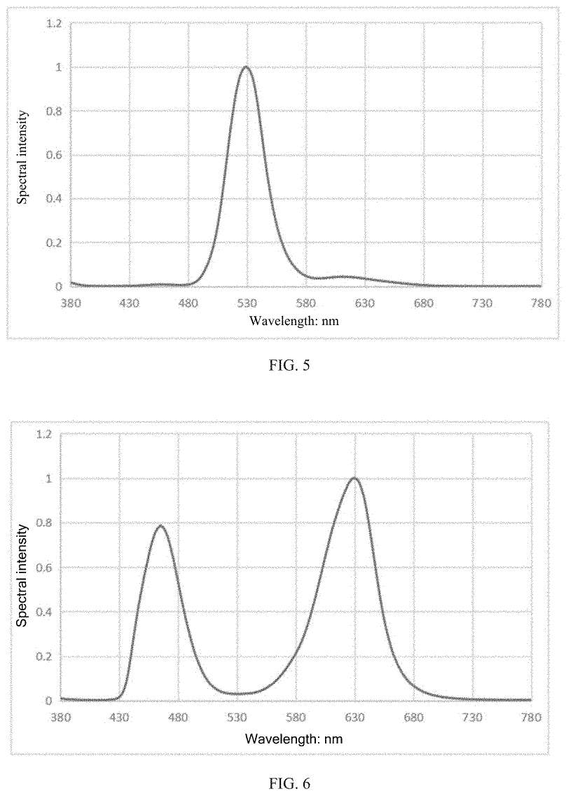

When the thickness of the organic layer of the OLED is 454 nm, only the resonance of the G light-emitting unit is enhanced. In this case, the spectrogram is shown in FIG. 5, and the photoelectric properties of the OLED structure using the light-emitting photoelectric parameters of the R and B pixels are shown in Table 2.

TABLE 2

| J (mA/cm²) | C.E(cd/A) | CIE-x | CIE-y | R-peak | G-peak | B-peak | FWHM- R | FWHM- G | FWHM- B |
|---|---|---|---|---|---|---|---|---|---|
| 10 | 20 | 0.41 | 0.23 | 630 | / | 469 nm | 38 nm | / | 40 nm |

When the thickness of the organic layer of the OLED is 524 nm, the resonance of the R light-emitting unit and the resonance of the B light-emitting unit are both enhanced. In this case, the spectrogram is shown in FIG. 6, and the photoelectric properties of the OLED structure using the light-emitting photoelectric parameters of the G pixels are shown in Table 3.

TABLE 3

| J (mA/cm²) | C.E(cd/A) | CIE-x | CIE-y | R-peak | G-peak | B-peak | FWHM- R | FWHM- G | FWHM- B |
|---|---|---|---|---|---|---|---|---|---|
| 10 | 43 | 0.22 | 0.71 | / | 529 | / | / | 28 | / |

The above experimental data also show that when the thickness of the organic layer of the OLED structure is 454 nm, only the resonance of the G light-emitting unit is enhanced, and when the thickness of the organic layer of the OLED structure is 524 nm, the resonance of the R light-emitting unit and the resonance of the B light-emitting unit are both enhanced. Thickness compensation is performed by the sum of the thickness of the R light-emitting unit and the thickness of the B light-emitting unit. In this way, in the R and B pixel regions, R light and B light are emitted, while in the G pixel region, only the G light is emitted. Finally, the color filter layer cooperates to achieve a full-color display. It should be noted that, in the present disclosure, R denotes a red pixel, B denotes a blue pixel, and G denotes a green pixel.

In conclusion, the full-color silicon-based OLED structure and the preparation method thereof provided by the present disclosure overcome the problems in the prior art that R, G, and B spectra cannot appear at the same time due to different lengths of R, G, and B resonant cavities, the color gamut of the product is low due to large intensity differences, and the product life is affected due to large light loss caused by the color filter.

The preferred implementations of the present disclosure are described above in detail with reference to the drawings, but the present disclosure is not limited to the specific details in the above implementations. Simple variations can be made to the technical solutions of the present disclosure without departing from the technical ideas of the present disclosure, and these simple variations fall within the protection scope of the present disclosure.

In addition, it should be noted that various specific technical features described in the above specific implementations can be combined in any suitable manner if there is no contradiction. To avoid unnecessary repetition, various possible combination modes of the present disclosure are not described separately.

In addition, different implementations of the present disclosure can also be combined arbitrarily. The combinations should also be regarded as falling within the scope of the present disclosure, provided that they do not violate the ideas of the present disclosure.

What is claimed is:

1. A full-color silicon-based organic light-emitting diode (OLED) structure, comprising a metal anode layer, an organic functional layer, a metal cathode layer, a polarizer layer, an encapsulation layer, and a color filter layer, wherein the metal anode layer, the organic functional layer, the metal cathode layer, the polarizer layer, the encapsulation layer, and the color filter layer are sequentially stacked from bottom to top, and wherein
the organic functional layer comprises a light-emitting layer configured to emit a white light toward the metal cathode layer;
the light-emitting layer comprises a red (R) light-emitting unit, a blue (B) light-emitting unit, a green (G) light-emitting unit, and a light-emitting common transport layer, wherein
the R light-emitting unit and the B light-emitting unit are vapor-deposited on a fine metal mask (FMM), so the R light-emitting unit and the B light-emitting unit share a microcavity; other structural film layers of the full-color silicon-based OLED structure are vapor-deposited on a common metal mask (CMM); and in the light-emitting layer, d_{FB}−d_{G}=d_{EML-R}+d_{EML-B}, wherein
d_{FB} denotes a thickness of a first organic layer of the full-color silicon-based OLED structure, and the first organic layer corresponds to the R light-emitting unit and the B light-emitting unit;
d_{G} denotes a thickness of a second organic layer of the full-color silicon-based OLED structure, and the second organic layer corresponds to the G light-emitting unit;
d_{EML-R} denotes a thickness of the R light-emitting unit; and
d_{EML-B} denotes a thickness of the B light-emitting unit.

2. The full-color silicon-based OLED structure according to claim 1, wherein a sum of the thickness of the R light-emitting unit and the thickness of the B light-emitting unit is:
d_{EML-R}+d_{EML-B}=70N, wherein
N is a positive integer, and the thickness is in nanometers (nm).

3. The full-color silicon-based OLED structure according to claim 2, wherein
the thickness d_{EML-R} of the R light-emitting unit is 35 nm-45 nm; and
the thickness d_{EML-B} of the B light-emitting unit is 25 nm-35 nm.

4. The full-color silicon-based OLED structure according to claim 1,
wherein the color filter layer comprises an R filter and a B filter,
wherein the R filter and the B filter are coated on light-emitting regions of the encapsulation layer, and
wherein the light-emitting regions correspond to the R light-emitting unit and the B light-emitting unit, respectively.

5. The full-color silicon-based OLED structure according to claim 1,
wherein the organic functional layer further comprises a hole injection layer, a hole transport layer, an electron transport layer, and an electron injection layer, wherein the hole injection layer, the hole transport layer, the electron transport layer, and the electron injection layer are sequentially arranged from bottom to top.

6. A method of preparing the full-color silicon-based OLED structure according to claim 1, comprising:
calculating the thickness of the first organic layer and the thickness of the second organic layer of the full-color silicon-based OLED structure respectively by Eq. (1), wherein the first organic layer and the second organic layer correspond to the R light-emitting unit, the B light-emitting unit, and the G light-emitting unit;
calculating a sum of the thickness of the R light-emitting unit and the thickness of the B light-emitting unit by Eq. (2), wherein Eq. (1) is:
$$\sum {nd}_{i} + \frac{ϕ}{4 π} {λ}_{i} = {m}_{i} \times \frac{{λ}_{i}}{2} ;$$
wherein n denotes a refractive index of the organic functional layer in the full-color silicon-based OLED structure; dᵢ denotes a thickness of the organic functional layer; λᵢ denotes a resonance-enhanced wavelength of the microcavity in the full-color silicon-based OLED structure; ϕ denotes a phase shift of a light reflected on surfaces of the metal anode layer and the metal cathode layer in the full-color silicon-based OLED structure; mᵢ denotes an order of an emission mode, also known as a microcavity order, and is a first positive integer; and i denotes a type of a light-emitting unit;
Eq. (2) is:
d_{FB}−d_{G}=d_{EML-R}+d_{EML-B};
wherein d_{FB} denotes the thickness of the first organic layer of the full-color silicon-based OLED structure, and the first organic layer corresponds to the R light-emitting unit and the B light-emitting unit;
d_{G} denotes the thickness of the second organic layer of the full-color silicon-based OLED structure and the second organic layer corresponds to the G light-emitting unit;
d_{EML-R} denotes the thickness of the R light-emitting unit; and
d_{EML-B} denotes the thickness of the B light-emitting unit;
selecting each of structural film layers with a corresponding thickness in the full-color silicon-based OLED structure according to a calculation result; and
vapor-depositing each of the structural film layers.

7. The method of preparing the full-color silicon-based OLED structure according to claim 6, wherein the vapor-depositing each of the structural film layers comprises:
S101: vapor-depositing a hole injection layer and a hole transport layer on the CMM;
S102: vapor-depositing the B light-emitting unit on the FMM;
S103: vapor-depositing the light-emitting common transport layer on the CMM;
S104: vapor-depositing the G light-emitting unit on the CMM;
S105: vapor-depositing the R light-emitting unit on the FMM;
S106: vapor-depositing an electron transport layer and an electron injection layer on the CMM; and
S107: vapor-depositing the metal cathode layer and the encapsulation layer on the CMM.

8. The method of preparing the full-color silicon-based OLED structure according to claim 6, wherein in the Eq. (1):
n is 1.75; and
λ_{R} is 618 nm, λ_{G} is 530 nm, and λ_{B} is 460 nm.

9. The method of preparing the full-color silicon-based OLED structure according to claim 6, wherein
a microcavity order m_{R} corresponding to the R light-emitting unit is 3 N;
a microcavity order m_{B} corresponding to the B light-emitting unit is 4 N; and
a microcavity order m_{G} corresponding to the G light-emitting unit is 3 N, and
wherein the N is a second positive integer.

10. The method of preparing the full-color silicon-based OLED structure according to claim 7, wherein following the vapor-depositing the metal cathode layer and the encapsulation layer on the CMM in the S107, the method further comprises:
S108: coating, by a photolithography process, the color filter layer on light-emitting regions of the encapsulation layer, wherein the light-emitting regions correspond to the R light-emitting unit and the B light-emitting unit, respectively, and
wherein the color filter layer comprises an R filter and a B filter.

11. The method of preparing the full-color silicon-based OLED structure according to claim 6, wherein a sum of the thickness of the R light-emitting unit and the thickness of the B light-emitting unit is:
d_{EML-R}+d_{EML-B}=70 N, wherein
N is a positive integer, and the thickness is in nanometers (nm).

12. The method of preparing the full-color silicon-based OLED structure according to claim 11, wherein
the thickness d_{EML-R} of the R light-emitting unit is 35 nm-45 nm; and
the thickness d_{EML-B} of the B light-emitting unit is 25 nm-35 nm.

13. The method of preparing the full-color silicon-based OLED structure according to claim 6,
wherein the color filter layer comprises an R filter and a B filter,
wherein the R filter and the B filter are coated on light-emitting regions of the encapsulation layer, and
wherein the light-emitting regions correspond to the R light-emitting unit and the B light-emitting unit, respectively.

14. The method of preparing the full-color silicon-based OLED structure according to claim 6, wherein the organic functional layer further comprises a hole injection layer, a hole transport layer, an electron transport layer, and an electron injection layer, wherein the hole injection layer, the hole transport layer, the electron transport layer, and the electron injection layer are sequentially arranged from bottom to top.

15. The method of preparing the full-color silicon-based OLED structure according to claim 8, wherein
a microcavity order m_{R} corresponding to the R light-emitting unit is 3 N;
a microcavity order m_{B} corresponding to the B light-emitting unit is 4 N; and
a microcavity order m_{G} corresponding to the G light-emitting unit is 3 N, and
wherein the N is a second positive integer.
